(19) United States
(12) Patent Application Publication
(10) Pub. No.: US 2017/0090236 A1
(43) Pub. Date: Mar. 30, 2017

(54) Bonding Pads for Displays

(71) Applicant: Apple Inc., Cupertino, CA (US)

(72) Inventors: Shin-Hung Yeh, Taipei City (TW); Sungki Lee, Sunnyvale, CA (US); Abbas Jamshidi Roudbari, Sunnyvale, CA (US); Cheng-Ho Yu, Cupertino, CA (US); Jiun-Jye Chang, Cupertino, CA (US); Ting-Kuo Chang, Cupertino, CA (US); Yu Cheng Chen, San Jose, CA (US); Yun Wang, San Jose, CA (US)

(21) Appl. No.: 14/992,894

(22) Filed: Jan. 11, 2016

Related U.S. Application Data
(60) Provisional application No. 62/233,892, filed on Sep. 28, 2015.

(51) Int. Cl. G02F 1/1345; G02F 1/1343; G02F 1/1333; G02F 1/1368; H01L 29/786; H01L 27/12

(52) U.S. Cl. CPC G02F 1/13458; H01L 29/78675; H01L 29/78633; H01L 27/1222; H01L 27/124; G02F 1/13338; G02F 1/1368; G02F 1/13439; G02F 1/13452; G02F 1/13306

(57) ABSTRACT

A display may have an array of pixels that forms an active display area for displaying images. An inactive border area of the display may have contact pads to which integrated circuits and flexible printed circuits may be attached. The contact pads may be free of organic planarization layers and may be formed from multiple stacked conductive layers. The inactive portion of the display may include electrostatic discharge protection structures associated with the pads, metal layers that form signal paths extending between the pads and the pixels, interlayer dielectric layers for protecting the metal layers that form the signal paths, polysilicon footer structures that help prevent undercutting of gate insulator material in the vicinity of the pads, and other pad and signal line structures.

This application claims the benefit of provisional patent application No. 62/233,892, filed Sep. 28, 2015, which is hereby incorporated by reference herein in its entirety.

### BACKGROUND

This relates generally to electronic devices and, more particularly, to electronic devices with displays.

Electronic devices often include displays. A display may have an active area with an array of pixels for displaying images. Display driver circuitry is used to control operation of the pixels. The display driver circuitry may include integrated circuits. The integrated circuits may be coupled to the display using a “chip-on-glass” arrangement in which the integrated circuits are attached directly to a display substrate or may be coupled to the display using a “flex-on-glass” arrangement in which a flexible printed circuit that carries display driver signals is attached to the display substrate.

Anisotropic conductive film adhesive is sometimes used in making electrical connections between contacts on an integrated circuit or flexible printed circuit and corresponding contact pads on a display substrate. If care is not taken, there is a risk that the layers of a display in the vicinity of the contact pads may become damaged due to stresses imparted by the anisotropic conductive film. For example, there is a risk that stresses such as these may cause organic planarization layers at the edges of the pads to delaminate.

It would therefore be desirable to be able to provide improved contact pad arrangements for components such as displays.

### SUMMARY

A display may have an array of pixels that forms an active display area for displaying images. An inactive border that runs along an edge of the display may have contact pads to which integrated circuits and flexible printed circuits may be attached.

The pixels may be formed from thin-film transistor circuitry that includes semiconductor material such as a polysilicon layer, conductive material such as indium tin oxide and metal, and insulating material. The insulating material may include interlayer dielectric layers and planarization layers. The interlayer dielectric layers may be formed from oxides, nitrides, or other inorganic materials and the planarization layers may be formed from organic layers such as polymer layers.

The contact pads may be free of the planarization layers and may be formed from multiple stacked conductive layers. The stacked conductive layers may include, for example, stacked metal layers and stacked indium tin oxide layers.

The inactive portion of the display may include electrostatic discharge protection structures associated with the pads, metal layers that form signal paths extending between the pads and the pixels, interlayer dielectric layers for protecting the metal layers that form the signal paths, polysilicon footer structures that help prevent undercutting of gate insulator material in the vicinity of the pads, and other pad and signal line structures.

Further features will be more apparent from the accompanying drawings and the following detailed description.

### BRIEF DESCRIPTION OF THE DRAWINGS

FIG. 1 is a diagram of an illustrative electronic device having a display in accordance with an embodiment.

FIG. 2 is a diagram of an illustrative display showing illustrative pad regions in which integrated circuits and flexible printed circuits may be attached to the display in accordance with an embodiment.

FIG. 3 is a cross-sectional side view of an illustrative display showing the locations of illustrative thin-film layers in accordance with an embodiment.

FIG. 4 is a side view of an illustrative component being attached to pads on a display in accordance with an embodiment.

FIG. 5 is a top view of an illustrative display showing an illustrative location for a chip-on-glass pad in accordance with an embodiment.

FIG. 6 is a cross-sectional side view of thin-film structures for forming the chip-on-glass pad of FIG. 5 in accordance with an embodiment.

FIG. 7 is a top view of an illustrative display showing an illustrative location for a flex-on-glass pad in accordance with an embodiment.

FIG. 8 is a cross-sectional side view of thin-film structures for forming the flex-on-glass pad of FIG. 7 in accordance with an embodiment.

FIG. 9 is a top view of an edge portion of an illustrative display that uses a semiconducting-oxide layer as an etch stop in accordance with an embodiment.

FIGS. 10 and 11 are cross-sectional side views of the illustrative display of FIG. 9 in accordance with an embodiment.

### DETAILED DESCRIPTION

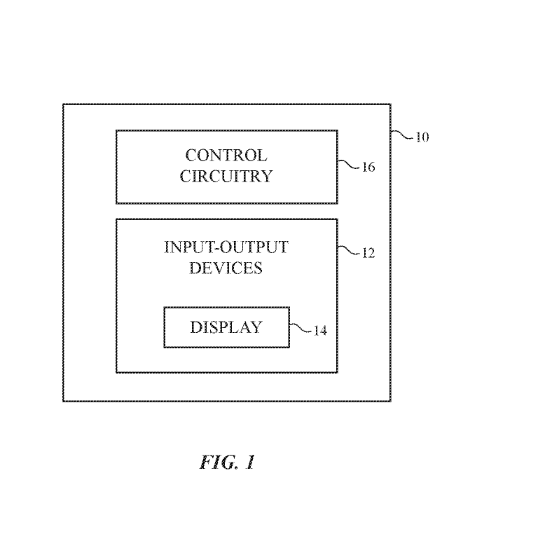

An illustrative electronic device of the type that may be provided with a display is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Display 14 may be a liquid crystal display, an organic light-emitting diode display, or other suitable display. Illustrative configurations in which display 14 is a liquid crystal display may sometimes be described herein as an example.

Control circuitry 16 may be used to run software on device 10 such as operating system code and applications. During operation of device 10, the software running on control circuitry 16 may display images on display 14.

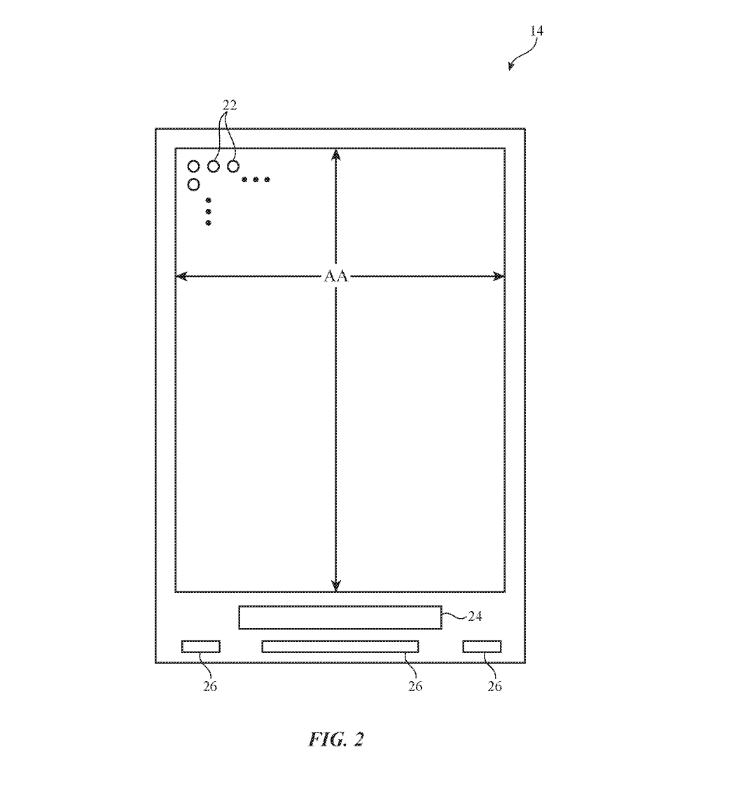

FIG. 2 is a diagram of an illustrative display. As shown in FIG. 2, display 14 may have an active area AA. Active area AA may contain an array of pixels 22 for displaying images for a user. One or more inactive border regions may run along the edges of active area AA.

Display driver circuitry (sometimes referred to as display circuitry or display control circuitry) may be used to control the operation of pixels 22. The display driver circuitry may be formed from integrated circuits, thin-film transistor circuits, or other suitable circuitry. As an example, the display driver circuitry for display 14 may contain one or more integrated circuits that are mounted directly to display 14 (e.g., in regions such as region 24) using a chip-on-glass arrangement ad may contain one or more integrated circuits that are mounted on a flexible printed circuit that is, in turn, mounted to display 14 (e.g. in regions such as regions 26).

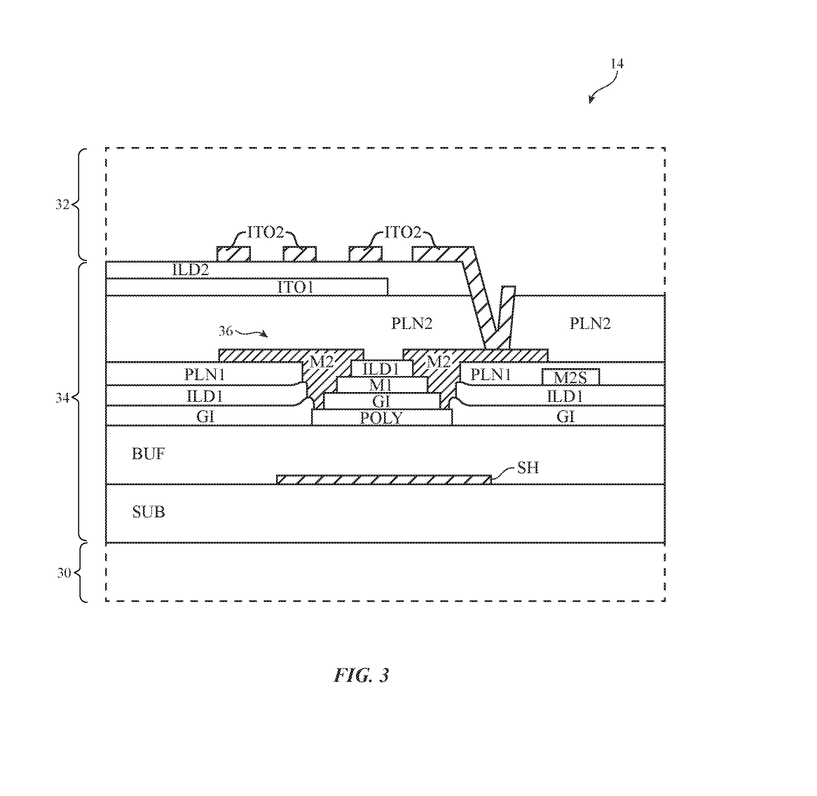

To enhance device reliability, it would be desirable to be able to form reliable contact pads in display 14. A cross-sectional side view of a portion of the active area AA of display 14 is shown in FIG. 3. In region 30, display 14 may have a backlight unit that generates backlight illumination. The backlight illumination passes through thin-film transistor circuitry 34 (sometimes referred to as a thin-film transistor layer), which forms an array of pixels 22. In region 32, display 14 may include a color filter layer and a liquid crystal layer interposed between the color filter layer and thin-film circuitry 34. Layers 32 and thin-film transistor circuitry 34 may be sandwiched between upper and lower polarizers.

Thin-film transistor circuitry 34 may include a substrate layer such as substrate SUB. Substrate SUB may be formed from transparent glass, plastic, or other materials. Light shield structure SH may be formed under thin-film transistors such as illustrative transistor 36. Light shield structure SH may be formed from metal (as an example). Dielectric buffer layer(s) BUF may be formed on substrate SUB. Thin-film transistor circuitry 34 may also include dielectric layers such as gate insulator layer GI and interlayer dielectric layers ILD1 and ILD2. Dielectric layers such as layers BUF, GI, ILD1, and ILD2 may be formed form silicon oxide, silicon nitride, other inorganic materials, or other insulators. Dielectric planarization layers such as layers PLN1 and PLN2 may be formed from organic layers (e.g., polymers) or other insulators.

Conductive layers such as layers ITO1 and ITO2 may be formed from indium tin oxide or other transparent conductive material. Layer ITO2 may be patterned to form electrode fingers for a pixel electrode driven by thin-film transistor 36. Layer ITO2 may be separated from a common voltage (Vcom) layer formed from layer ITO1 by interlayer dielectric layer ILD2. Transistor 36 may have a channel formed from polysilicon layer POLY, gate and source terminals formed from metal layer M2, and a gate formed from metal layer M1 (which is separated from the channel by gate insulator GI). Intermediate metal layer M2S may be interposed between interlayer dielectric layer ILD1 and planarization layer PLN1 and may be used to form signal interconnects. Other display structures may be formed using the layers of FIG. 3 and/or different thin-film layers may be include in display 14. The illustrative thin-film structures of FIG. 3 are merely illustrative.

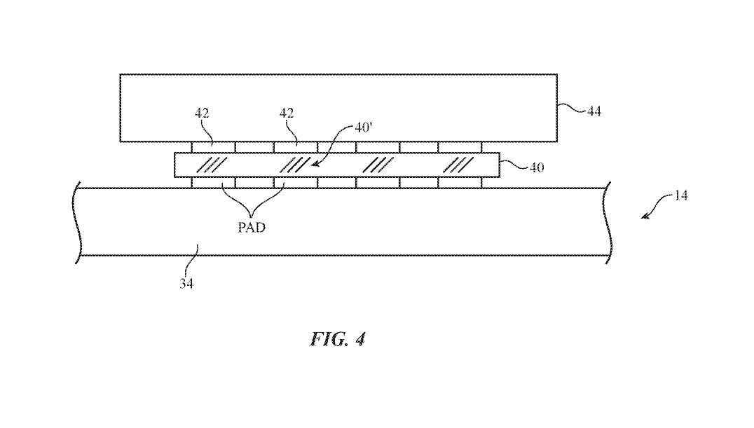

As shown in FIG. 4, the structures of thin-film transistor circuitry 34 may be patterned to form contact pads PAD. Pads PAD may be formed in an inactive ledge portion of substrate SUB that is not covered with the color filter layer or liquid crystal layer of layers 32 of FIG. 3). Pads PAD may be coupled to corresponding contacts 42 on mating component 44 (e.g., an integrated circuit or flexible printed circuit to which an integrated circuit is mounted). Conductive material 40 may be used to form electrical connections between contacts 42 on component 44 and pads PAD. Conductive material 40 may be, for example, anisotropic conductive film that forms conductive paths 40′ wherever the film is locally compressed between a pad (PAD) and corresponding contact 42.

The use of conductive materials such as anisotropic conductive film in coupling component 44 to display 14 allows satisfactory electrical connections to be made, but can impose stresses on contact pads. It would therefore be desirable to be able to form robust pad structures on display 14.

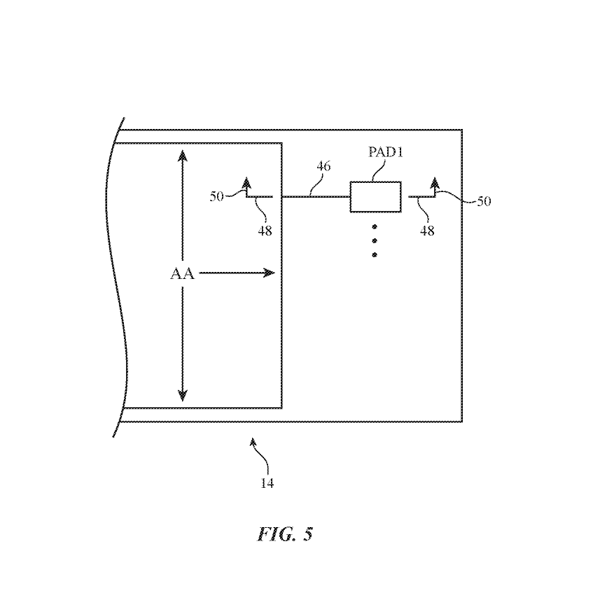

A top view of an edge portion of display 14 with illustrative chip-on-glass pads PAD1 is shown in FIG. 5. As shown in FIG. 5, pads PAD1 may be coupled to the circuitry of pixels 22 in active area AA using signals lines 46. Signal lines 46 may extend across the inactive border to couple pads PAD1 to pixels in active area AA. There may be any suitable number of pads PAD1 on display 14 (e.g., 10 or more, 50 or more, 100 or more, less than 1000, or other suitable number). Pads such as PAD1 are preferably constructed using thin-film structures that resist delamination and other damage when subjected to stress during the formation of anisotropic conductive film bonds and other bonds.

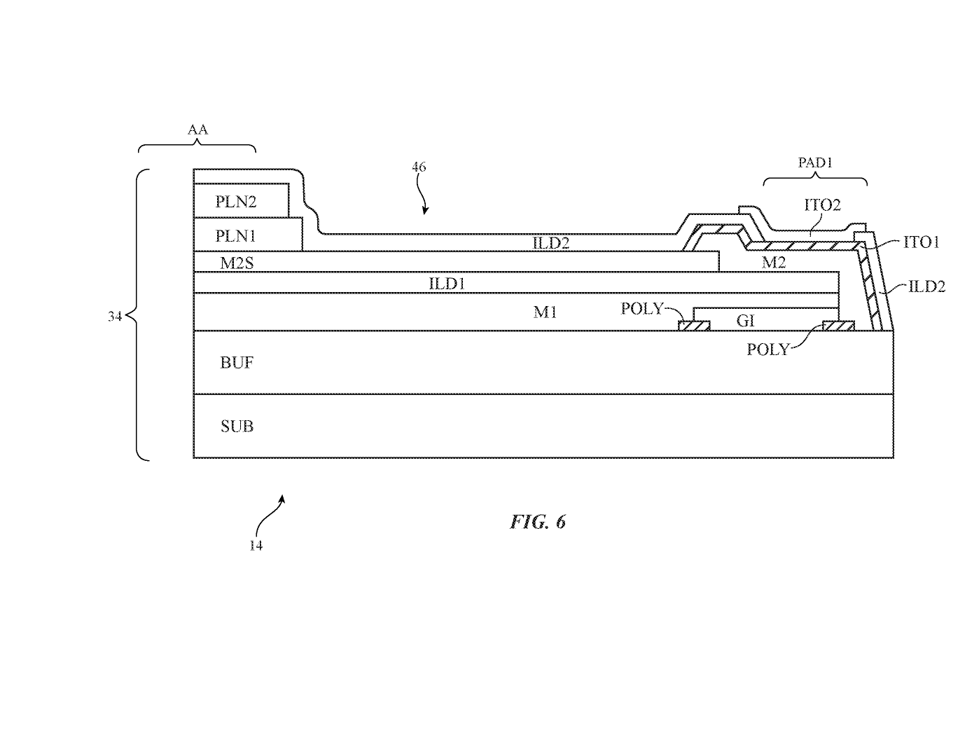

A cross-sectional side view of a portion of active area AA, signal line 46, and pad PAD1 of FIG. 5 taken along line 48 and viewed in direction 50 is shown in FIG. 6. As shown in FIG. 6, PAD1 may be formed from a stack of conductive layers on substrate layer SUB, dielectric layer BUF, and gate insulator GI. The conductive layers that make up PAD1 may include metal M1 on gate insulator GI, metal M2 on metal M1, conductive layer ITO1 on metal M2, and conductive layer ITO2 on conductive layer ITO1. PAD1 may be formed within an opening formed in dielectric layers ILD1 and ILD2.

In the arrangement of FIG. 6, organic planarization layers PLN1 and PLN2 have been removed from the surface of signal line 46 and the vicinity of pad PAD1. Planarization layers PLN1 and PLN2 may exhibit lower adhesion than other thin-film layers, so eliminating layers PLN1 and PLN2 from the region surrounding PAD1 may help enhance the reliability of PAD1 (i.e., planarization layer peeling may be avoided by ensuring that none of the peripheral edge of PAD1 is covered with planarization layer material and by ensuring that inactive area signal lines such as line 46 are not covered with planarization layers).

Signal line 46 may be formed using metal layer M1. To provide environmental protection for metal M1, metal M1 may be covered with dielectric layer ILD1. Additional protection may be provided using layer ILD2. Layer ILD1 may have a thickness of about 0.3 to 0.4 microns and layer ILD2 may have a thickness of about 0.15 microns (as an example). By using both ILD2 and ILD1 to cover M1, the total insulation thickness for metal layer M1 is increased.

It may be desirable to pattern planarization layer PLN1 and layer ILD1 using a common mask to reduce mask count. To allow ILD1 and PLN1 to have different patterns in the inactive border of display 14, metal layer M2S may be used as an etch stop when removing planarization layer PLN1 using dry etching.

There may be a risk of undercutting gate insulator GI when etching gate insulator GI on layer BUF. Polysilicon footer structures POLY may be provided around the periphery of gate insulator GI under PAD1 (i.e., between gate insulator layer GI and layer BUF) to help prevent gate insulator undercutting. By preventing undercutting, the formation of voids under metal M1 following deposition of metal M1 may be avoided. Footers POLY may also help prevent metal contact to the glass of substrate SUB by protecting layer BUF near the edges of PAD1.

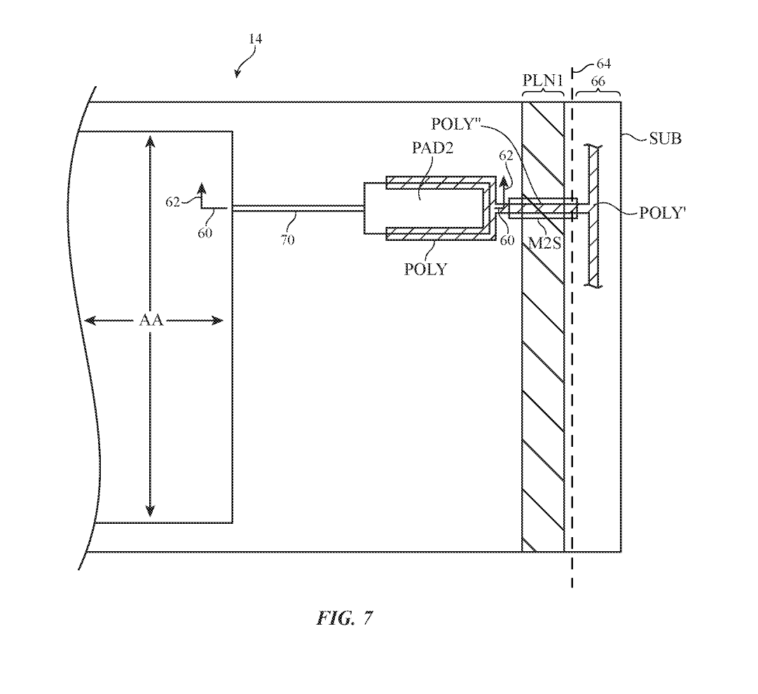

A top view of an edge portion of display 14 with illustrative flex-on-glass pads PAD2 is shown in FIG. 7. As shown in FIG. 7, pads PAD2 may be coupled to the circuitry of pixels 22 in active area AA using signals lines 70. There may be any suitable number of pads PAD2 on display 14 (e.g., 10 or more, 50 or more, 100 or more, less than 1000, or other suitable number). As with pads PAD1 in the example of FIGS. 5 and 6, pads such as PAD2 are preferably constructed using thin-film structures that resist delamination and other damage when subjected to stress during the formation of anisotropic conductive film bonds or other bonds.

The display structures of FIG. 7 include removable substrate portion 66. Portion 66 may be removed during display processing by cutting substrate SUB along cut line 64. During fabrication, the structures of FIG. 7 may be subjected to electrostatic discharge events. To prevent damage to the thin-film circuitry of display 14, a sacrificial guard ring structure such as guard ring POLY′ may be formed on region 66. As shown in FIG. 7, a polysilicon guard ring line POLY″ may be used to couple guard ring POLY′ to a strip of polysilicon POLY that runs around at least part of the periphery of PAD2. To protect line POLY″ during dry etching to remove unwanted thin-film layers, line POLY″ may be covered with a strip of metal layer M2S. A strip of planarization layer PLN1 that does not overlap PAD2 may also be used to protect POLY along the border of display 14.

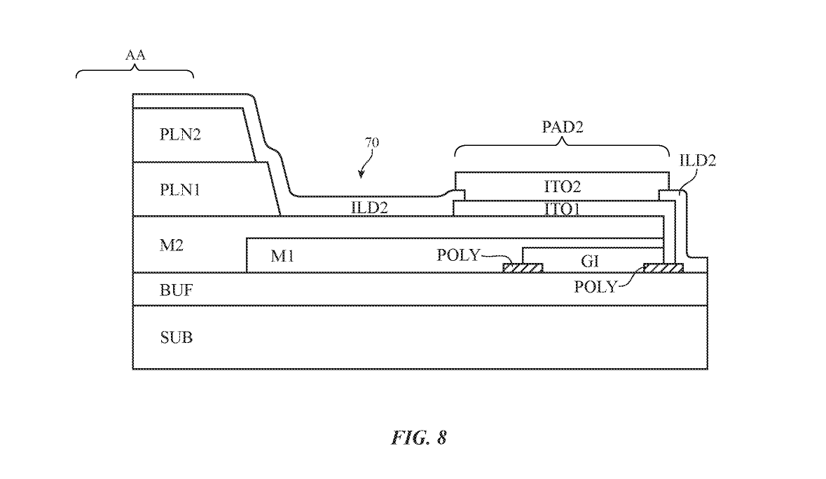

A cross-sectional side view of a portion of active area AA, signal line 70, and pad PAD2 of FIG. 7 taken along line 60 and viewed in direction 62 is shown in FIG. 8. As described in connection with PAD1, PAD2 of FIG. 8 may be formed from a stack of conductive layers on substrate layer SUB, dielectric buffer layer BUF, and gate insulator layer GI. In particular, the conductive layers that make up PAD2 may include metal M1 on gate insulator GI, metal M2 on metal M1, conductive layer ITO1 on metal M2, and conductive layer ITO2 on conductive layer ITO1. PAD2 may be formed within a region that is free of dielectric layers ILD1 and ILD2.

In the arrangement of FIG. 8, organic planarization layers PLN1 and PLN2 have been removed from the surface of signal line 70 and the edge of pad PAD1 (i.e., both line 70 in the inactive area of display 14 and the edge and other portions of pad PAD1 are not overlapped by planarization layers and are therefore free of planarization layer material to help enhance the reliability of PAD2).

Signal line 70 may be formed using metal layer M1 and metal layer M2. Metal layer M2 may be thicker than layer M1 and may therefore help lower the resistance of line 70. Metal layers M1 and M2 may be covered with dielectric layer ILD2 to provide environmental protection for metal M1 and M2. As with PAD1, PAD2 may incorporate polysilicon footers (POLY in FIG. 8) to help reduce the risk of undercutting gate insulator layer GI when etching gate insulator GI on layer BUF. Polysilicon footer structures POLY may be provided around the periphery of gate insulator GI under PAD2 between gate insulator layer GI and layer BUF.

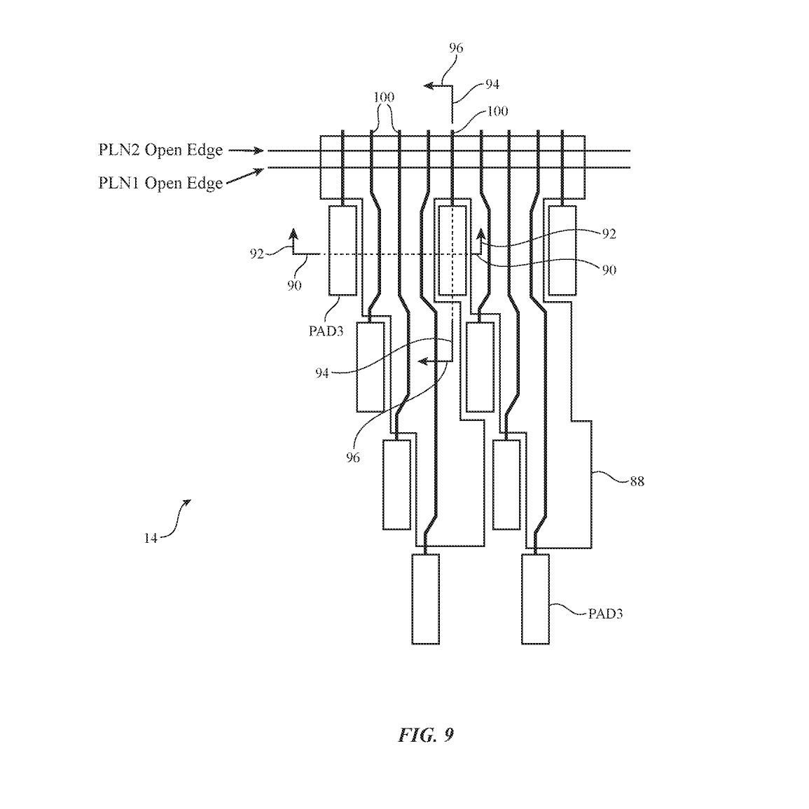

If desired, materials such as semiconducting oxides may be used in forming the semiconductor channels of the transistors in the thin-film transistor circuitry of display 14. For example, thin-film transistors may have semiconductor channel regions (active regions) formed from a semiconducting-oxide material such as indium gallium zinc oxide (IGZO) or other semiconducting oxide. In arrangements such as these, the semiconducting-oxide layer may be used in forming an etch stop during processing of the pads for display 14. FIG. 9 is a top view of an edge portion of display 14 in this type of configuration. As shown in FIG. 9, display 14 may have an edge region in organic planarization layers PLN1 and PLN2 have been removed from the surface of signal lines 100 and pads PAD3. Planarization layers PLN1 and PLN2 may exhibit lower adhesion than other thin-film layers, so eliminating layers PLN1 and PLN2 from the region surrounding pads PAD3 may help enhance the reliability of pads PAD3. Iridium gallium zinc oxide layer 88 may overlap signal lines 100 without overlapping pads PAD3.

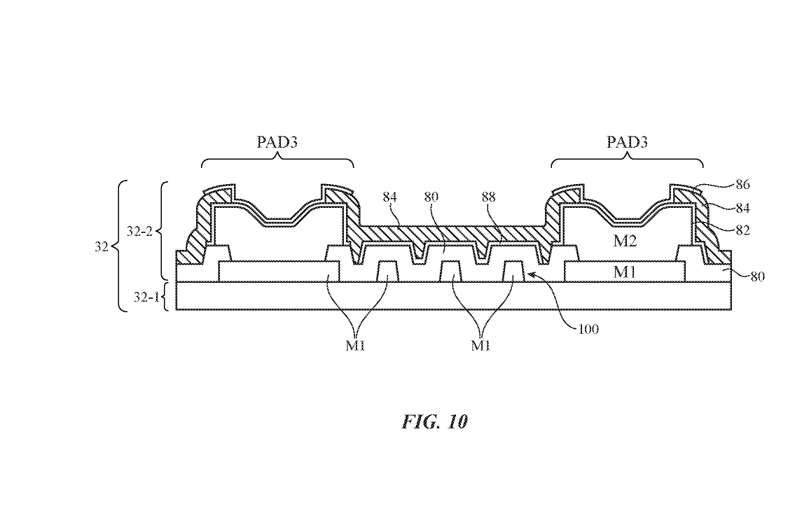

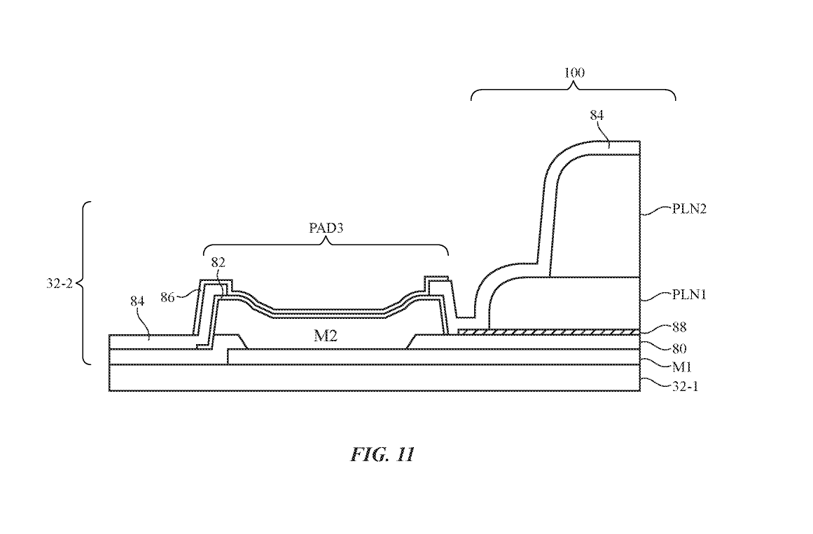

A cross-sectional side view of the edge portion of display 14 of FIG. 9 taken along line 90 and viewed in direction 92 is shown in FIG. 10. A cross-sectional side view of the edge portion of display 14 of FIG. 9 taken along line 94 and viewed in direction 96 is shown in FIG. 11. In FIGS. 10 and 11, thin-film circuitry 32-2 is formed on substrate layer(s) 32-1. Layer(s) 32-1 may include, for example, a glass substrate layer (SUB), a buffer layer (BUF), and a gate insulator layer (GI).

As shown in FIG. 10, pads such as pads PADS may be formed from stacked conductive layers such as first metal layer M1, second metal layer M1, a first indium tin oxide (ITO) layer such as layer 82 (e.g., a Vcom layer), and a second indium tin oxide (ITO) layer such as layer 86 (e.g., a layer for forming pixel electrodes). Lines 100 may be formed from metal layer M1. Dielectric layer 80 (e.g., a first interlayer dielectric layer) may cover lines 100. Dielectric layer 84 (e.g., a second interlayer dielectric layer) may overlap lines 100 and may separate first ITO layer 82 from second ITO layer 86 in active area AA of display 14.

To prevent etching of layers such as layers 80 and M1 (e.g., lines 100) during etching (e.g., etching to remove planarization layer PLN1 and/or other etching operations), a portion of semiconducting-oxide layer (IGZO layer) 88 may overlap some of layer 80 and metal lines 100 along the inactive border of display 14 and may serve as an etch stop in this portion of display 14. In active area AA, layer 88 may be patterned to form the semiconductor channel regions of thin-film transistors in the thin-film circuitry for pixels 22.

The foregoing is merely illustrative and various modifications can be made by those skilled in the art without departing from the scope and spirit of the described embodiments. The foregoing embodiments may be implemented individually or in any combination.

1. A display, comprising:
an array of pixels that displays images, wherein the array of pixels has thin-film circuitry that includes at least one organic planarization layer;
at least one contact pad that has a peripheral edge that is not overlapped by the organic planarization layer; and
a signal line that extends between the contact pad and the thin-film circuitry in the array of pixels and that has at least a portion that is not overlapped by the organic planarization layer.

2. The display defined in claim 1 wherein the thin-film transistor circuitry comprises a gate insulator layer and wherein a portion of the gate insulator layer is overlapped by the contact pad.

3. The display defined in claim 2 wherein the array of pixels has a substrate coated with a dielectric layer, the display further comprising:
polysilicon footer structures under an edge of the portion of the gate insulator layer that is overlapped by the contact pad, wherein at least a portion of the polysilicon footer structures is interposed between the portion of the gate insulator layer and the substrate.

4. The display defined in claim 3 wherein the substrate comprises glass.

5. The display defined in claim 4 wherein the thin-film transistor circuitry comprises at least first, second, and third metal layers and wherein the signal line is formed from the first metal layer.

6. The display defined in claim 5 further comprising at least first and second interlayer dielectric layers, wherein a portion of the first interlayer dielectric layer covers the signal line formed from the first metal layer and is not overlapped by the organic planarization layer.

7. The display defined in claim 6 further comprising an etch stop layer formed from a portion of the second metal layer that overlaps the first interlayer dielectric layer that covers the signal line formed from the first metal layer.

8. The display defined in claim 7 wherein a portion of the second interlayer dielectric layer overlaps the etch stop layer.

9. The display defined in claim 8 wherein the contact pad includes portions of the first and third metal layers.

10. The display defined in claim 9 wherein the thin-film transistor circuitry includes first and second indium tin oxide layers and wherein the contact pad includes portions of the first and second indium tin oxide layers.

11. The display defined in claim 1 wherein the thin-film transistor circuitry includes at least one transparent conductive layer and wherein the contact pad includes a portion of the transparent conductive layer.

12. The display defined in claim 11 wherein the thin-film transistor circuitry comprises at least first, second, and third metal layers, wherein the signal line is formed from the first metal layer, and wherein the contact pad includes portions of the first and third metal layers.

13. The display defined in claim 1 further comprising an interlayer dielectric layer, wherein a portion of the interlayer dielectric layer covers the signal line formed from a first metal layer and is not overlapped by the organic planarization layer.

14. The display defined in claim 13 further comprising an etch stop layer that covers at least some of the interlayer dielectric layer.

15. The display defined in claim 14 wherein the etch stop layer comprises a semiconducting-oxide layer.

16. The display defined in claim 15 wherein the semiconducting-oxide layer comprises indium gallium zinc oxide.

17. A display, comprising:
an array of pixels that displays images, wherein the array of pixels has thin-film circuitry that includes at least one organic planarization layer;
at least one contact pad that has a peripheral edge that is not overlapped by the organic planarization layer; and
a signal line that extends between the contact pad and the thin-film circuitry in the array of pixels and that has a portion that is not overlapped by the organic planarization layer, wherein the thin-film transistor circuitry includes at least first and second metal layers and wherein the pad includes portions of the first and second metal layers.

18. The display defined in claim 17 wherein the thin-film transistor circuitry comprises first and second transparent conductive layers and wherein the contact pad includes portions of the first and second transparent conductive layers.

19. The display defined in claim 18 wherein the first and second transparent conductive layers comprise respective first and second indium tin oxide layers.

20. The display defined in claim 18 wherein the signal line includes portions of the first and second metal layers.

21. The display defined in claim 20 wherein the array of pixels has a substrate coated with a dielectric layer, wherein the thin-film transistor circuitry comprises a gate insulator layer, and wherein a portion of the gate insulator layer is overlapped by the contact pad, the display further comprising:
polysilicon footer structures under an edge of the portion of the gate insulator layer that is overlapped by the contact pad, wherein at least a portion of the polysilicon footer structures is interposed between the portion of the gate insulator layer and the substrate.

22. The display defined in claim 21 wherein the polysilicon footer structures are formed from part of a polysilicon layer, wherein the polysilicon layer comprises a polysilicon line that extends from the contact pad towards an edge of the display and forms part of an electrostatic discharge protection guard ring structure.

23. The display defined in claim 22 wherein the thin-film transistor circuitry further comprises an additional metal layer having a portion that overlaps the polysilicon line.

24. The display defined in claim 17 wherein the signal line includes a portion of the first metal layer and is not overlapped by the organic planarization layer, the display further comprising:
an interlayer dielectric layer that covers the signal line;
a semiconducting-oxide etch stop layer that covers at least some of the interlayer dielectric layer and that overlaps at least some of the signal line.

25. A display, comprising:
an active area having an array of pixels formed from thin-film circuitry, wherein the thin-film transistor circuitry includes first and second organic planarization layers, first and second interlayer dielectric layers, first and second metal layers, an additional metal layer interposed between the first organic polarization layer and the first interlayer dielectric layer, and two indium tin oxide layers;
a contact pad that is not overlapped by the first and second organic planarization layers, wherein the contact pad includes portions of the first and second metal layers and portions of the two indium tin oxide layers; and
a signal line that is formed from a portion of the first metal layer and that extends between the contact pad and the array of pixels, wherein a portion of the first interlayer dielectric layer overlaps the signal line and wherein a portion of the additional metal layer overlaps the portion of the first interlayer dielectric that overlaps the signal line.
